(19) United States
(12) Patent Application Publication
(10) Pub. No.: US 2023/0197711 A1
(43) Pub. Date: Jun. 22, 2023

(54) AI CHIP

(71) Applicant: Panasonic Intellectual Property Management Co., Ltd., Osaka (JP)

(72) Inventors: Shoichi GOTO, Kanagawa (JP); Koji OBATA, Osaka (JP); Masaru SASAGO, Osaka (JP); Masamichi NAKAGAWA, Osaka (JP)

(21) Appl. No.: 17/995,972

(22) PCT Filed: Apr. 14, 2021
(86) PCT No.: PCT/JP2021/015475

§ 371 Date: Oct. 11, 2022

(30) Foreign Application Priority Data
May 28, 2020 (JP) 2020-093022

(51) Int. Cl. H01L 27/06; H01L 25/065; G11C 5/02; H01L 27/02; G06N 3/065

(52) U.S. Cl. CPC H01L 27/0688; H01L 25/0657; G11C 5/02; H01L 27/0207; G06N 3/065

(57) ABSTRACT

An artificial intelligence (AI) chip includes: a plurality of memory dies each for storing data; a plurality of computing dies each of which performs a computation included in an AI process; and a system chip that controls the plurality of memory dies and the plurality of computing dies. Each of the plurality of memory dies has a first layout pattern. Each of the plurality of computing dies has a second layout pattern. A second memory die which is one of the plurality of memory dies is stacked above the first layout pattern of a first memory die which is one of the plurality of memory dies. A second computing die which is one of the plurality of computing dies is stacked above the second layout pattern of a first computing die which is one of the plurality of computing dies.

### CROSS-REFERENCE OF RELATED APPLICATIONS

This application is the U.S. National Phase under 35 U.S.C. § 371 of International Patent Application No. PCT/JP2021/015475, filed on Apr. 14, 2021, which in turn claims the benefit of Japanese Patent Application No. 2020-093022, filed on May 28, 2020, the entire disclosures of which Applications are incorporated by reference herein.

### TECHNICAL FIELD

The present disclosure relates to AI chips.

### BACKGROUND ART

Patent Literature (PTL) 1 discloses a semiconductor integrated circuit device including a system-on-chip provided with a plurality of logic macros and a memory chip with a memory space to be accessed by the logic macros stacked on the system-on-chip. A plurality of memory chips can be stacked to increase the amount of memory.

### CITATION LIST

### Patent Literature

[PTL 1] WO 2010/021410

### SUMMARY OF INVENTION

### Technical Problem

In recent years, various computations using artificial intelligence (AI; hereinafter referred to as AI processes) have been expected to be performed at high speed. A semiconductor integrated circuit with the configuration as disclosed in PTL 1 may be applied to the AI processes. However, computations themselves cannot be performed by the semiconductor integrated circuit at higher speed even with an increased amount of memory. An increase in the processing power requires, for example, redesign of the chips and is difficult to achieve.

Thus, the present disclosure has an object of providing an AI chip of which processing power can be easily increased.

### Solution to Problem

An AI chip according to an aspect of the present disclosure includes: a plurality of memory dies each for storing data; a plurality of computing dies each of which performs a computation included in an AI process; and a system chip that controls the plurality of memory dies and the plurality of computing dies, wherein each of the plurality of memory dies has a first layout pattern, each of the plurality of computing dies has a second layout pattern, a second memory die which is one of the plurality of memory dies is stacked above the first layout pattern of a first memory die which is one of the plurality of memory dies, and a second computing die which is one of the plurality of computing dies is stacked above the second layout pattern of a first computing die which is one of the plurality of computing dies.

### Advantageous Effects of Invention

According to the AI chip according to the present disclosure, processing power thereof can be easily increased.

### BRIEF DESCRIPTION OF DRAWINGS

FIG. 1 is a schematic perspective view of AI chip 1 according to an embodiment.

FIG. 2 is a block diagram illustrating a configuration of a system chip included in an AI chip according to the embodiment.

FIG. 3 is a diagram schematically illustrating a relationship between the block diagram illustrated in FIG. 2 and the perspective view illustrated in FIG. 1

FIG. 4 is a plan view illustrating an example of a plan layout of memory dies according to the embodiment.

FIG. 5 is a plan view illustrating an example of a plan layout of computing dies according to the embodiment.

FIG. 6 is a block diagram illustrating a configuration of AI process blocks provided for computing dies according to the embodiment.

FIG. 7 is a cross-sectional view illustrating an example where TSVs are used in connecting the plurality of memory dies and the plurality of computing dies according to the embodiment.

FIG. 8 is a cross-sectional view illustrating an example where wireless communication is used in connecting the plurality of memory dies and the plurality of computing dies according to the embodiment.

FIG. 9 is a schematic perspective view of an AI chip according to Variation 1 of the embodiment.

FIG. 10 is a schematic perspective view of a first example of an AI chip according to Variation 2 of the embodiment.

FIG. 11 is a schematic perspective view of of a second example of an AI chip according to Variation 2 of the embodiment.

FIG. 12 is a schematic perspective view of of a third example of an AI chip according to Variation 2 of the embodiment.

FIG. 13 is a schematic perspective view of of a fourth example of an AI chip according to Variation 2 of the embodiment.

### DESCRIPTION OF EMBODIMENTS

### Overview of Present Disclosure

An AI chip according to an aspect of the present disclosure includes: a plurality of memory dies each for storing data; a plurality of computing dies each of which performs a computation included in an AI process; and a system chip that controls the plurality of memory dies and the plurality of computing dies. Each of the plurality of memory dies has a first layout pattern. Each of the plurality of computing dies has a second layout pattern. A second memory die which is one of the plurality of memory dies is stacked above the first layout pattern of a first memory die which is one of the plurality of memory dies. A second computing die which is one of the plurality of computing dies is stacked above the second layout pattern of a first computing die which is one of the plurality of computing dies.

Thus, required numbers of memory dies and computing dies can be stacked to increase the amount of memory and the computing power, respectively. That is, the performance of the AI chip can be easily changed in a scalable manner. As a result, the processing power of the AI chip can be easily increased.

Furthermore, for example, the system chip may include the first memory die and the first computing die.

This eliminates the need for an interposer, resulting in a reduction in the cost of the AI chip.

Furthermore, for example, the system chip may include an interposer, and at least one of the first memory die or the first computing die may be stacked on the interposer.

In a case where the interposer is used, the processing power of the AI chip can be increased by redesigning only the memory dies and/or the computing dies, not the overall system chip.

Furthermore, for example, the first memory die and the first computing die may be stacked on the interposer.

This provides greater flexibility in arranging the memory dies and the computing dies.

Furthermore, for example, the system chip may include a first region and a second region that do not overlap with each other in plan view. The plurality of memory dies may be stacked in the first region, and the plurality of computing dies may be stacked in the second region.

In this case, the memory dies and the computing dies are stacked separately, allowing the layout pattern of the memory dies and the layout pattern of the computing dies to be completely different. The layout patterns of the memory dies and the computing dies can be separately optimized.

Furthermore, for example, one of the first memory die and the first computing die may be stacked above an other of the first memory die and the first computing die.

This allows the memory dies and the computing dies to be stacked in the same region and thus reduces the area of the system chip.

Furthermore, for example, each of the plurality of computing dies may include a programmable circuit, and the programmable circuit may include an accelerator circuit for the AI process.

This enables the AI process to be performed at higher speed while the circuits are programmable.

Furthermore, for example, the programmable circuit may include a logic block and a switch block.

This enables other logical operations, as well as the AI process, to be performed at high speed.

Furthermore, for example, the computation included in the AI process may include at least one of convolution operation, matrix operation, or pooling operation.

This enables the AI process to be performed at higher speed.

Furthermore, for example, the convolution operation may include a computation performed in a logarithmic domain.

This enables computations to be performed using only addition, without using multiplication, and thus enables the AI process to be performed at higher speed. Moreover, the area of the computing dies can be reduced.

Furthermore, for example, the AI process may include error diffusion dithering.

Using dithering eliminates or minimizes degradation of accuracy even with a small number of bits.

Furthermore, for example, the system chip may include: a control block; and a bus that electrically connects the control block to the plurality of memory dies and the plurality of computing dies.

This enables complex processes to be performed only by the AI chip.

Furthermore, for example, the plurality of first layout patterns may be interconnected by through conductors.

This enables the memory dies to be easily electrically interconnected, thereby enabling data and signals to be transmitted and received.

Furthermore, for example, the plurality of first layout patterns may be interconnected wirelessly.

This enables data and signals to be easily transmitted and received between the memory dies through wireless communication. This also reduces the cost of the AI chip.

Furthermore, for example, the plurality of second layout patterns may be interconnected by through conductors.

This enables the computing dies to be easily electrically interconnected, thereby enabling data and signals to be transmitted and received.

Furthermore, for example, the plurality of second layout patterns may be interconnected wirelessly.

This enables data and signals to be easily transmitted and received between the computing dies through wireless communication. This also reduces the cost of the AI chip.

Hereinafter, embodiments will be described in detail with reference to the Drawings.

It should be noted that each of the embodiments described below shows a generic or specific example. The numerical values, shapes, materials, elements, the arrangement and connection of the elements, steps, the processing order of the steps, etc., shown in the following embodiments are mere examples, and thus are not intended to limit the present disclosure. Furthermore, among the elements described in the following embodiments, elements not recited in any one of the independent claims are described as optional elements.

Furthermore, the respective figures are schematic diagrams, and are not necessarily precise illustrations. Therefore, the scale, etc., in the respective figures do not necessarily match. Furthermore, in the figures, elements which are substantially the same are given the same reference signs, and overlapping description is omitted or simplified.

The terms “above” and “below” mentioned herein are not in the absolute upward and downward directions (vertically upward and downward directions, respectively) in spatial perception but are defined by the relative positions of layers in the multilayer structure, which are based on the order of stacking of the layers. Moreover, the terms “above” and “below” are used to describe not only a situation in which two elements are spaced with another element therebetween, but also a situation in which two elements are in contact with each other.

### Embodiment

### 1. Overview

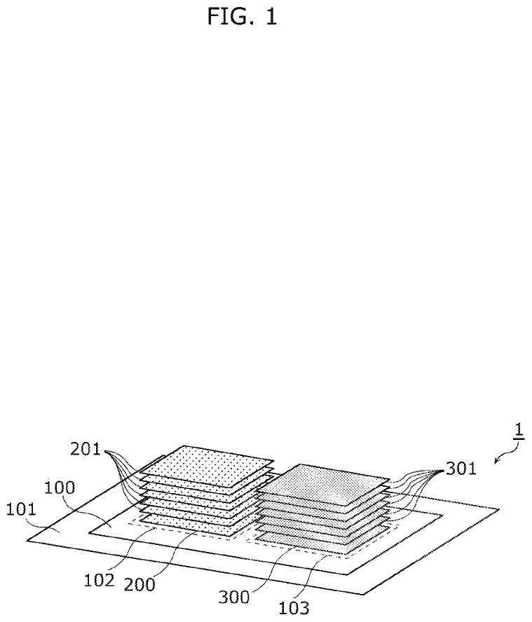

First, an overview of an AI chip according to an embodiment will be described with reference to FIG. 1. FIG. 1 is a schematic perspective view of AI chip 1 according to the present embodiment.

AI chip 1 illustrated in FIG. 1 is a semiconductor chip that performs an AI process. The AI process corresponds to various computations for using artificial intelligence and is used for, for example, natural language processing, speech recognition processing, image recognition processing and recommendation, control of various devices, and the like. The AI process includes, for example, machine learning, deep learning, or the like.

As illustrated in FIG. 1, AI chip 1 is provided with system chip 100, package substrate 101, a plurality of memory dies 201 for storing data, and a plurality of computing dies 301 that perform computations included in the AI process. System chip 100 is mounted on package substrate 101. The plurality of memory dies 201 and the plurality of computing dies 301 are mounted on system chip 100. The plurality of memory dies 201 and the plurality of computing dies 301 are bare chips.

In the present embodiment, system chip 100 is provided with memory die 200 for storing data and computing die 300 that performs computations included in the AI process. Because of this, system chip 100 alone can perform the AI process (that is, without memory dies 201 and computing dies 301 stacked thereon). Memory dies 201 and computing dies 301 are additionally provided to increase the speed of the AI process. Required numbers of memory dies 201 and computing dies 301 are provided to increase the amount of memory and computing power, respectively.

The plurality of memory dies 201 are stacked above memory die 200. The amount of memory available for the AI process can be increased by increasing the number of memory dies 201. The number of memory dies 201 is determined according to the amount of memory required by AI chip 1. AI chip 1 is provided with at least one memory die 201. The amount of memory increases with the number of the memory dies.

The plurality of computing dies 301 are stacked above computing die 300. The computing power available for the AI process can be increased by increasing the number of computing dies 301. The number of computing dies 301 is determined according to the computing power required by AI chip 1. AI chip 1 is provided with at least one computing die 301.

The computing power is, for example, the number of commands executable per unit time (TOPS: Tera Operations Per Second). For example, one computing die 301 has a command execution capacity of 40 TOPS with one watt of power consumption. As illustrated in FIG. 1, AI chip 1 is provided with a stack of seven computing dies in total, including computing die 300. Thus, AI chip 1 has a command execution capacity of 280 TOPS with seven watts of power consumption. In this manner, the processing power of AI chip 1 increases with the number of computing dies.

In the present embodiment, the memory dies and the computing dies are stacked separately. That is, the plurality of memory dies and the plurality of computing dies are disposed in separate regions when system chip 100 is viewed in plan.

Specifically, as illustrated in FIG. 1, system chip 100 has first region 102 and second region 103. First region 102 is separate from second region 103 when viewed in plan.

Memory die 200 and the plurality of memory dies 201 are disposed in first region 102. Specifically, all memory dies 201 are stacked on memory die 200 disposed in first region 102. Memory die 200 and all memory dies 201 are superposed on each other when viewed in plan. One memory die 201 is stacked on one memory die 200 or 201.

Computing die 300 and the plurality of computing dies 301 are disposed in second region 103. Specifically, all computing dies 301 are stacked on computing die 300 disposed in second region 103. Computing die 300 and all computing dies 301 are superposed on each other when viewed in plan. One computing die 301 is stacked on one computing die 300 or 301.

As described above, required numbers of memory dies and computing dies can be stacked in AI chip 1. That is, to increase the amount of memory, a required number of memory dies 201 can be stacked. To increase the computing power, a required number of computing dies 301 can be stacked. To increase both the amount of memory and the computing power, required numbers of memory dies 201 and computing dies 301, respectively, can be stacked. Thus, the performance of AI chip 1 can be easily changed in a scalable manner. As a result, the processing power of AI chip 1 can be easily increased.

### 2. Configuration

Next, specific configurations of elements of AI chip 1 will be described.

### 2-1. System Chip

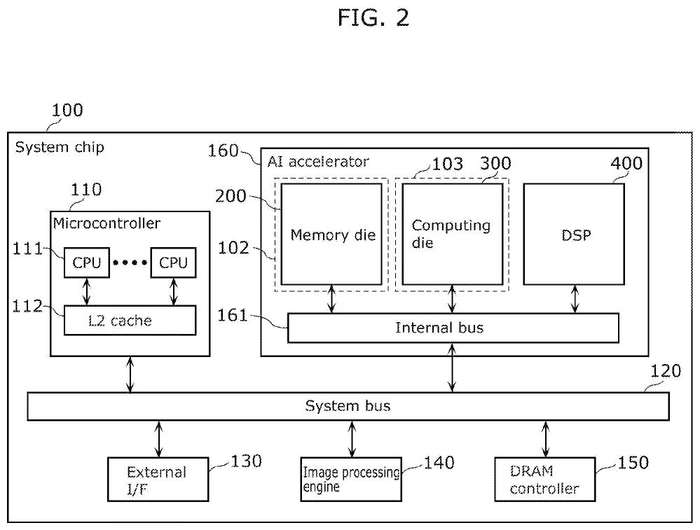

First, a configuration of system chip 100 will be described with reference to FIG. 2. FIG. 2 is a block diagram illustrating the configuration of system chip 100 included in AI chip 1 according to the present embodiment.

System chip 100 controls overall AI chip 1. Specifically, system chip 100 controls the plurality of memory dies 200 and 201 and the plurality of computing dies 300 and 301.

As illustrated in FIG. 2, system chip 100 is provided with microcontroller 110, system bus 120, external interface 130, image processing engine 140, DRAM (Dynamic Random Access Memory) controller 150, and AI accelerator 160.

Microcontroller 110 is an example of a control block that controls overall system chip 100. Microcontroller 110 transmits and receives data and information to and from external interface 130, image processing engine 140, DRAM controller 150, and AI accelerator 160 through system bus 120 to perform computations and execute commands. As illustrated in FIG. 2, microcontroller 110 is provided with a plurality of CPUs (Central Processing Units) 111 and L2 cache 112. Microcontroller 110 may be provided with only one CPU 111. Moreover, microcontroller 110 may not be provided with L2 cache 112.

Microcontroller 110 causes a memory die freely selected from memory die 200 and the plurality of memory dies 201 to store data required for the AI process. That is, data that can be stored in one of memory dies 200 and 201 can also be stored in other memory dies 200 and 201. Microcontroller 110 uses all stacked memory dies 201 as available memory spaces. In a case where new memory die 201 is stacked, microcontroller 110 can control new memory die 201 equally to existing memory die 200 or memory dies 201.

Moreover, microcontroller 110 causes a computing die freely selected from computing die 300 and the plurality of computing dies 301 to perform computations included in the AI process. That is, commands that can be executed by one of computing dies 300 and 301 can also be executed by other computing dies 300 and 301. Microcontroller 110 uses all stacked computing dies 301 as available computing circuits. In a case where new computing die 301 is stacked, microcontroller 110 can control new computing die 301 equally to existing computing die 300 or computing dies 301.

System bus 120 is wiring used to transmit and receive data, signals, and the like. Microcontroller 110, external interface 130, image processing engine 140, DRAM controller 150, and AI accelerator 160 are electrically connected to system bus 120 and can communicate with each other.

External interface 130 is an interface for transmitting and receiving data and signals to and from an external device separate from AI chip 1.

Image processing engine 140 is a signal processing circuit that processes image signals or video signals. For example, image processing engine 140 performs image quality adjustment or the like.

DRAM controller 150 is a memory controller that reads and writes data from and into an external memory separate from AI chip 1.

AI accelerator 160 is a signal processing circuit that performs the AI process at high speed. As illustrated in FIG. 2, AI accelerator 160 is provided with internal bus 161, memory die 200, computing die 300, and DSP (Digital Signal Processor) 400.

Internal bus 161 is wiring used to transmit and receive data, signals, and the like inside AI accelerator 160. Memory die 200, computing die 300, and DSP 400 are electrically connected to internal bus 161 and can communicate with each other. Internal bus 161 is also used to transmit and receive data, signals, and the like to and from the plurality of memory dies 201 and the plurality of computing dies 301. Internal bus 161 and system bus 120 constitute a bus that electrically connects microcontroller 110 to the plurality of memory dies 200 and 201 and the plurality of computing dies 300 and 301.

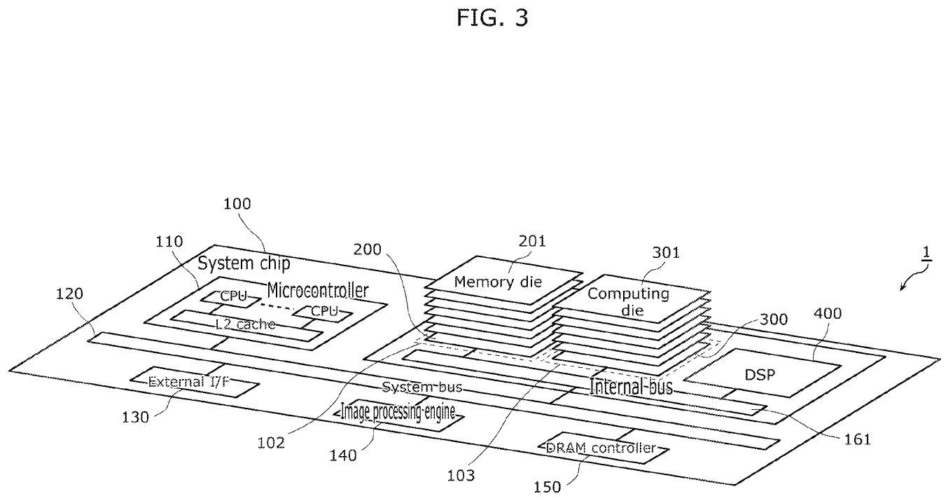

Memory die 200 is an example of a first memory die serving as one of the plurality of memory dies provided for AI chip 1. As illustrated in FIG. 3, the plurality of memory dies 201 are stacked above a layout pattern (first layout pattern) of memory die 200. Here, FIG. 3 schematically illustrates the relationship between the block diagram illustrated in FIG. 2 and the perspective view illustrated in FIG. 1. Each of the plurality of memory dies 201 is an example of a second memory die stacked above the first layout pattern of the first memory die.

Computing die 300 is an example of a first computing die serving as one of the plurality of computing dies provided for AI chip 1. As illustrated in FIG. 3, the plurality of computing dies 301 are stacked above a layout pattern (second layout pattern) of computing die 300. Each of the plurality of computing dies 301 is an example of a second computing die stacked above the second layout pattern of the first computing die.

DSP 400 is a processor that performs digital signal processing related to the AI process.

It should be noted that the configuration of system chip 100 is not limited to the example illustrated in FIG. 2. For example, system chip 100 may not be provided with image processing engine 140. System chip 100 may be provided with a signal processing circuit or the like dedicated to predetermined processes.

### 2-2. Memory Dies

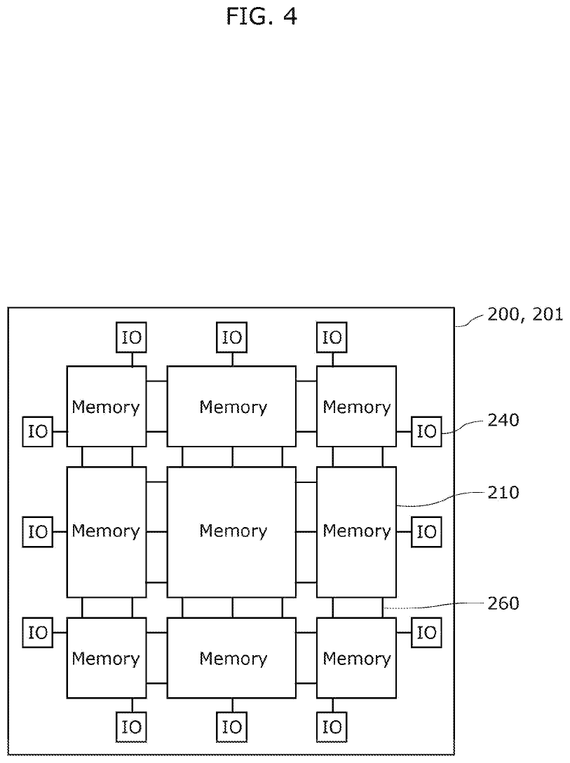

Next, a configuration of memory dies 200 and 201 will be described with reference to FIG. 4. FIG. 4 is a plan view illustrating an example of a plan layout of memory dies 200 and 201 provided for AI chip 1 according to the present embodiment.

Memory die 200 and the plurality of memory dies 201 have the same layout pattern. Specifically, memory die 200 and the plurality of memory dies 201 have the same configuration and the same amount of memory. The following primarily describes the configuration of memory dies 201.

Memory dies 201 are, for example, volatile memory, such as DRAM or SRAM. Memory dies 201 may be nonvolatile memory, such as NAND flash memory. As illustrated in FIG. 4, each of memory dies 201 is provided with one or more memory blocks 210, one or more input/output ports 240, and one or more wires 260. One or more memory blocks 210, one or more input/output ports 240, and one or more wires 260 are formed on the surfaces of or inside silicon substrates that constitute memory dies 201. The layout pattern of memory dies 201 are described by the sizes, shapes, numbers, and arrangements of memory blocks 210, input/output ports 240, and wires 260.

One or more memory blocks 210 are memory circuits each including one or more memory cells for storing data. In the example illustrated in FIG. 4, one or more memory blocks 210 vary in area (amount of memory). However, the areas of all memory blocks 210 may be the same.

One or more input/output ports 240 are terminals that input and output data and signals to and from memory dies 201. Each of memory dies 201 is electrically connected to memory die 200 or 201 stacked below itself and memory die 201 stacked above itself through input/output ports 240. Memory dies 201 are electrically connected to memory die 200 and electrically connected to internal bus 161 and system bus 120 through memory die 200. In the example illustrated in FIG. 4, one or more input/output ports 240 are arranged circularly along the outer perimeters of memory dies 201. However, the arrangement is not limited to this. For example, one or more input/output ports 240 may be arranged in the middles of memory dies 201.

One or more wires 260 are electrical wires that connect input/output ports 240 to memory blocks 210, and are used for data transmission and reception. One or more wires 260 include, for example, bit lines and word lines. One or more wires 260 in the example illustrated in FIG. 4 are arranged in a grid but may be arranged in stripes.

FIG. 4 schematically illustrates an example of a simplified configuration of memory dies 200 and 201. However, memory dies 200 and 201 may have any other configuration with the same layout pattern.

### 2-3. Computing Dies

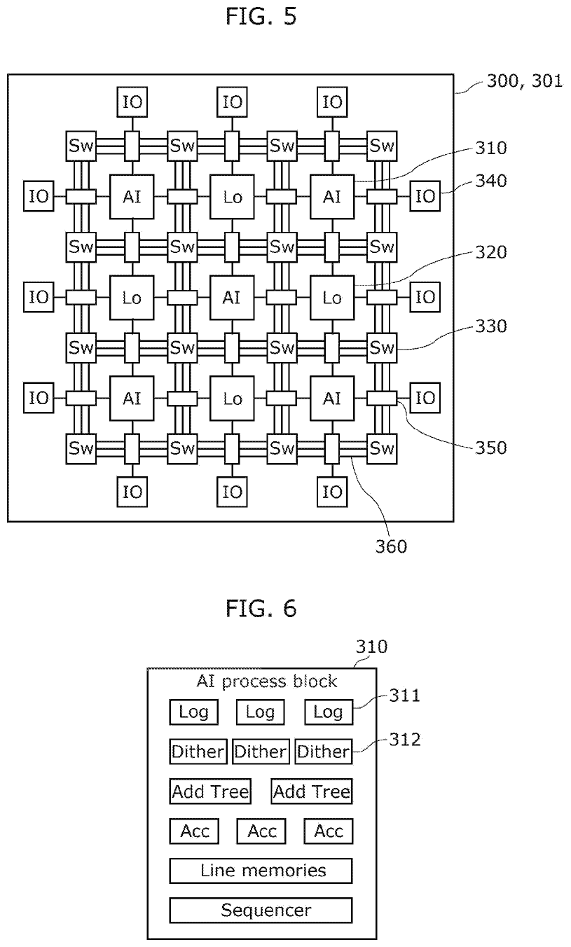

Next, a configuration of computing dies 300 and 301 will be described with reference to FIG. 5. FIG. 5 is a diagram illustrating an example of a plan layout of computing dies 300 and 301 provided for AI chip 1 according to the present embodiment.

Computing die 300 and the plurality of computing dies 301 have the same layout pattern. Specifically, computing die 300 and the plurality of computing dies 301 have the same configuration and the same computing power. The following primarily describes the configuration of computing dies 301.

Computing dies 301 include programmable circuits. Specifically, computing dies 301 are FPGAs (Field Programmable Gate Arrays). As illustrated in FIG. 5, each of computing dies 301 is provided with one or more AI process blocks 310, one or more logic blocks 320, one or more switch blocks 330, one or more input/output ports 340, one or more connection blocks 350, and one or more wires 360. One or more AI process blocks 310, one or more logic blocks 320, one or more switch blocks 330, one or more input/output ports 340, one or more connection blocks 350, and one or more wires 360 are formed on the surfaces of or inside silicon substrates that constitute computing dies 301. The layout pattern of computing dies 301 is described by the sizes, shapes, numbers, and arrangements of AI process blocks 310, logic blocks 320, switch blocks 330, input/output ports 340, connection blocks 350, and wires 360.

One or more AI process blocks 310 are accelerator circuits for the AI process. A specific configuration of AI process blocks 310 will be described later with reference to FIG. 6.

One or more logic blocks 320 are computing circuits that perform logical operations. One or more AI process blocks 310 and one or more logic blocks 320 are arranged in rows and columns. For example, in the example illustrated in FIG. 5, one or more AI process blocks 310 and one or more logic blocks 320 are arranged in a three by three array and are electrically connected by wires 360 through switch blocks 330 and connection blocks 350. The number of AI process blocks 310 may be, but not limited in particular to, one. Moreover, one or more AI process blocks 310 and one or more logic blocks 320 do not necessarily have to be arranged in rows and columns and may be arranged in stripes.

One or more switch blocks 330 are switching circuits that switch connections between two to four connection blocks 350 adjacent to respective switch blocks 330.

One or more input/output ports 340 are terminals that input and output data and signals to and from computing dies 301. Each of computing dies 301 is connected to computing die 300 or 301 stacked below itself and computing die 301 stacked above itself through input/output ports 340. Computing dies 301 are connected to computing die 300 and connected to internal bus 161 and system bus 120 through computing die 300. In the example illustrated in FIG. 5, one or more input/output ports 340 are arranged circularly along the outer perimeters of computing dies 301. However, the arrangement is not limited to this. For example, one or more input/output ports 340 may be arranged in the middles of computing dies 301.

One or more connection blocks 350 are circuits for connecting to AI process blocks 310, logic blocks 320, and switch blocks 330 adjacent to respective connection blocks 350.

One or more wires 360 are electrical wires that connect input/output ports 340 to AI process blocks 310, logic blocks 320, and the like, and are used for data transmission and reception. One or more wires 360 in the example illustrated in FIG. 5 are arranged in a grid but may be arranged in stripes.

Switching connections between input/output ports 340, AI process blocks 310, and logic blocks 320 using switch blocks 330 and connection blocks 350 enables computing dies 301 to perform specific computations. Switch blocks 330 and connection blocks 350 are switched using, for example, configuration information (configuration data) stored in memory (not illustrated).

Next, a specific configuration of AI process blocks 310 will be described with reference to FIG. 6. FIG. 6 is a block diagram illustrating the configuration of AI process blocks 310 provided for computing dies 300 and 301 according to the present embodiment.

AI process blocks 310 perform computations included in the AI process. Specifically, AI process blocks 310 perform at least one of convolution operation, matrix operation, or pooling operation. For example, as illustrated in FIG. 6, AI process blocks 310 each include logarithmic processing circuits 311. Logarithmic processing circuits 311 perform computations on logarithmically quantized input data. Specifically, logarithmic processing circuits 311 perform convolution operation on logarithmically quantized input data. Since the data to be computed is converted into the logarithmic domain, multiplication included in the convolution operation can be performed by addition. This enables the AI process to be performed at higher speed.

Moreover, the AI process performed by AI process blocks 310 may include error diffusion dithering. Specifically, AI process blocks 310 each include dither circuits 312. Dither circuits 312 perform computations using error diffusion. This eliminates or minimizes degradation of computational accuracy even with a small number of bits.

FIG. 5 schematically illustrates an example of a simplified configuration of computing dies 300 and 301. However, computing dies 300 and 301 may have any other configuration with the same layout pattern.

### 3. Interconnection Between Stacked Dies

Next, interconnection between stacked dies will be described. The dies can be interconnected by TSVs (Through Silicon Vias) or wirelessly.

### 3-1. TSVs

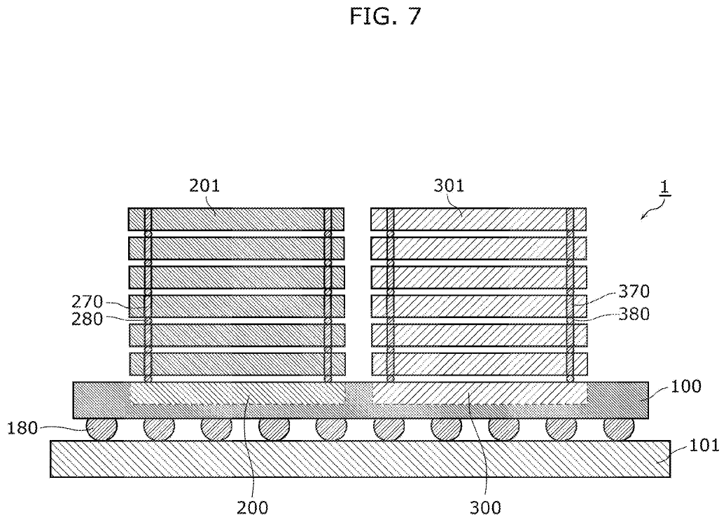

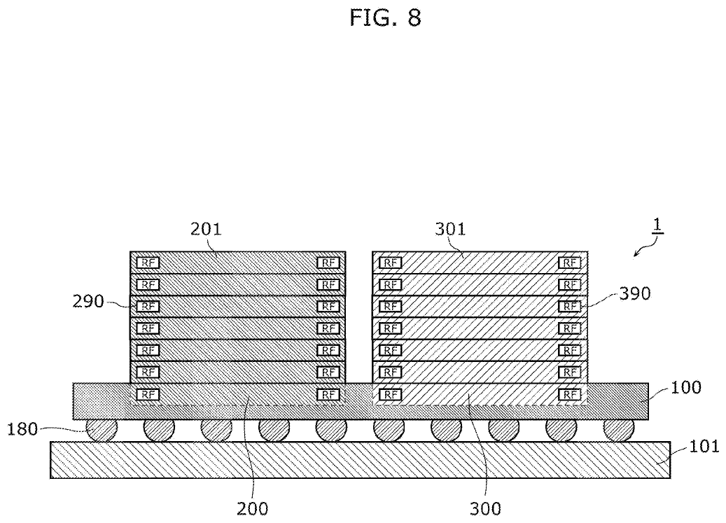

FIG. 7 is a cross-sectional view illustrating an example where the plurality of memory dies 201 and the plurality of computing dies 301 according to the present embodiment are connected by TSVs. FIG. 7 illustrates system chip 100 mounted on package substrate 101 through bump electrodes 180. Memory die 200 and computing die 300 are formed inside system chip 100 in an integrated manner and are schematically indicated using hatched areas that are bordered with broken lines in FIG. 7. The same applies to FIG. 8.

As illustrated in FIG. 7, each of the plurality of memory dies 201 is provided with TSVs 270. TSVs 270 are an example of through conductors that pass through memory dies 201. TSVs 270 are made of, for example, a metal material, such as copper (Cu). Specifically, TSVs 270 can be formed by creating through-holes that pass through memory dies 201 in the thickness direction, covering the inner walls of the through-holes with insulating films, and then filling the through-holes with a metal material by, for example, electroplating.

In FIG. 7, bump electrodes 280 are formed at at least first ends of TSVs 270 using a metal material, such as copper, to electrically interconnect TSVs 270 of memory dies 201 that are adjacent to each other in the stacking direction. Memory dies 201 adjacent to each other in the stacking direction may be connected without using bump electrodes 280.

When viewed in plan, TSVs 270 and bump electrodes 280 are superposed on input/output ports 240 illustrated in FIG. 4. In the present embodiment, memory die 200 and the plurality of memory dies 201 have the same layout pattern. Accordingly, the positions of input/output ports 240 coincide with each other when the stacked dies are viewed in plan. As a result, memory dies 201 can be easily electrically interconnected by TSVs 270 that pass through memory dies 201 in the thickness direction.

As are memory dies 201, each of the plurality of computing dies 301 is provided with TSVs 370. TSVs 370 are an example of through conductors that pass through computing dies 301. TSVs 370 are made of the same material and formed by the same method as TSVs 270.

In FIG. 7, bump electrodes 380 are formed at at least first ends of TSVs 370 using a metal material, such as copper, to electrically interconnect TSVs 370 of computing dies 301 that are adjacent to each other in the stacking direction. Computing dies 301 adjacent to each other in the stacking direction may be connected without using bump electrodes 380.

When viewed in plan, TSVs 370 and bump electrodes 380 are superposed on input/output ports 340 illustrated in FIG. 5. In the present embodiment, computing die 300 and the plurality of computing dies 301 have the same layout pattern. Accordingly, the positions of input/output ports 340 coincide with each other when the stacked dies are viewed in plan. As a result, computing dies 301 can be easily electrically interconnected by TSVs 370 that pass through computing dies 301 in the thickness direction.

To electrically connect memory die 201 in the top layer to memory die 200 in the bottom layer, all memory dies 201 except for memory die 201 in the top layer are provided with TSVs 270. Similarly, to electrically connect memory die 201 in the second layer from the top to memory die 200, all memory dies 201 except for memory die 201 in the top layer and memory die 201 in the second layer from the top are provided with TSVs 270. At this moment, TSVs 270 used to connect memory die 201 in the top layer and TSVs 270 used to connect memory die 201 in the second layer from the top may be the same TSVs to be shared or may be separate TSVs that are not to be shared. The same applies to computing dies 301.

### 3-2. Wireless

FIG. 8 is a cross-sectional view illustrating an example where the plurality of memory dies 201 and the plurality of computing dies 301 according to the present embodiment are connected wirelessly. Wireless connection is also referred to as wireless TSV technology.

As illustrated in FIG. 8, each of the plurality of memory dies 201 is provided with wireless communication circuits 290. Wireless communication circuits 290 communicate wirelessly in a very short communication range of tens of micrometers. Specifically, wireless communication circuits 290 include small coils and communicate using magnetic coupling between the coils.

As are memory dies 201, each of the plurality of computing dies 301 is provided wireless communication circuits 390. Wireless communication circuits 390 communicate wirelessly in a very short communication range of tens of micrometers. Specifically, wireless communication circuits 390 include small coils and communicate using magnetic coupling between the coils.

FIG. 8 illustrates an example where wireless communication circuits 290 and 390 are embedded in the respective substrates. However, the configuration is not limited to this. Wireless communication circuits 290 and 390 may be disposed on at least the upper surfaces or the lower surfaces of the respective substrates.

Memory dies 201 may be connected by TSVs, whereas computing dies 301 may be connected wirelessly. Alternatively, memory dies 201 may be connected wirelessly, whereas computing dies 301 may be connected by TSVs. Moreover, memory dies 201 may be connected both by TSVs and wireless. Similarly, computing dies 301 may be connected both by TSVs and wireless.

### 4. Variations

Next, variations of AI chip 1 according to the embodiment will be described. The following primarily describes differences from the above-described embodiment, and descriptions of common features will be omitted or simplified.

### 4-1. Variation 1

First, an AI chip according to Variation 1 will be described. In Variation 1, an interposer is used to stack at least the memory dies or the computing dies.

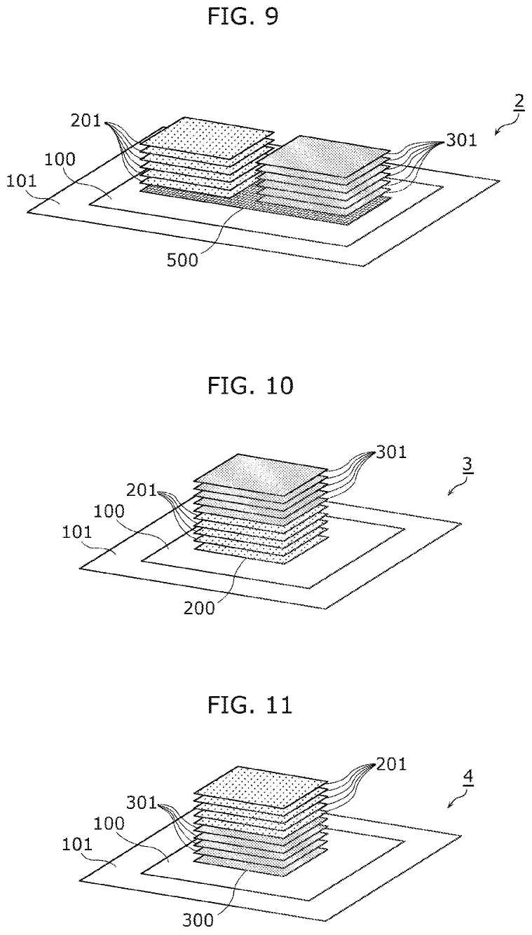

FIG. 9 is a schematic perspective view of AI chip 2 according to Variation 1. As illustrated in FIG. 9, in AI chip 2, system chip 100 is provided with interposer 500. System chip 100 is not provided with either memory die 200 or computing die 300.

Interposer 500 is a relay part that relays electrical connection between the chip and the substrates. In this variation, one of the plurality of memory dies 201 and one of the plurality of computing dies 301 are stacked on interposer 500. The rest of memory dies 201 is stacked above memory die 201 stacked on interposer 500. The rest of computing dies 301 is stacked above computing die 301 stacked on interposer 500.

In this variation, system chip 100 may be provided with either memory die 200 or computing die 300. In other words, only the memory dies or the computing dies may be stacked on interposer 500.

For example, AI chip 2 may be provided with one or more memory dies 201 stacked above memory die 200 provided for system chip 100 and the plurality of computing dies 301 stacked on interposer 500. Alternatively, AI chip 2 may be provided with one or more computing dies 301 stacked above computing die 300 provided for system chip 100 and the plurality of memory dies 201 stacked on interposer 500.

### 4-2. Variation 2

Next, an AI chip according to Variation 2 will be described. In Variation 2, the memory dies and the computing dies are mixed in one stack.

FIGS. 10 to 13 are schematic perspective views of AI chips 3 to 6, respectively, according to Variation 2.

In AI chip 3 illustrated in FIG. 10, system chip 100 is provided with memory die 200 but is not provided with computing die 300. The plurality of memory dies 201 and the plurality of computing dies 301 are stacked above memory die 200 in this order. That is, computing die 301 in the bottom layer of the plurality of computing dies 301 is stacked on memory die 201 in the top layer of the plurality of memory dies 201.

As in AI chip 4 illustrated in FIG. 11, the plurality of memory dies 201 may be stacked above the plurality of computing dies 301. In AI chip 4, system chip 100 is provided with computing die 300 but is not provided with memory die 200. The plurality of computing dies 301 and the plurality of memory dies 201 are stacked above computing die 300 in this order. That is, memory die 201 in the bottom layer of the plurality of memory dies 201 is stacked on computing die 301 in the top layer of the plurality of computing dies 301.

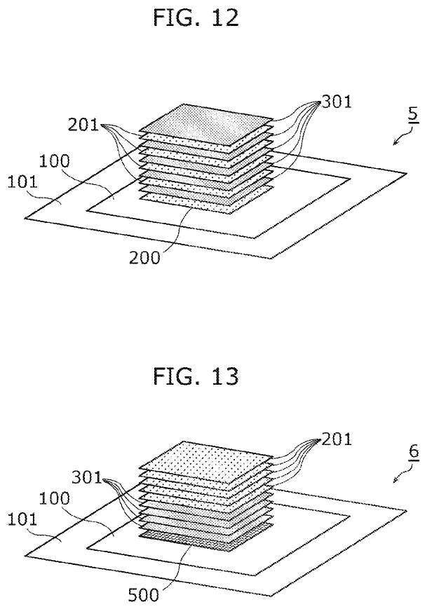

Alternatively, as in AI chip 5 illustrated in FIG. 12, memory dies 201 and computing dies 301 may be stacked alternately. In AI chip 5, system chip 100 is provided with memory die 200 but is not provided with computing die 300. Computing dies 301 and memory dies 201 are stacked on memory die 200 alternately one by one. In AI chip 5, system chip 100 may be provided with computing die 300 but may not be provided with memory die 200. Memory dies 201 and computing dies 301 may be stacked on computing die 300 alternately one by one. Moreover, in AI chip 5, system chip 100 may be provided with memory die 200 and computing die 300. Memory dies 201 and computing dies 301 may be stacked above memory die 200 and computing die 300 alternately one by one. Moreover, at least memory dies 201 or computing dies 301 may be stacked in sets of multiple dies.

Moreover, as in AI chip 6 illustrated in FIG. 13, memory dies 201 and computing dies 301 may be stacked on interposer 500. In AI chip 6, system chip 100 is provided with interposer 500 but is not provided with either memory die 200 or computing die 300. One of the plurality of computing dies 301 is stacked on interposer 500. The rest of computing dies 301 and memory dies 201 are stacked above computing die 301 stacked on interposer 500. Memory dies 201 may be stacked on interposer 500. Moreover, memory dies 201 and computing dies 301 stacked over interposer 500 may be stacked alternately one by one or stacked in sets of multiple dies.

As has been described, the method of stacking the memory dies and the computing dies is not particularly limited. This provides AI chips with great flexibility in changing the design.

### Other Embodiments

Although AI chips according to one or more aspects have been described above based on the foregoing embodiments, these embodiments are not intended to limit the present disclosure. The scope of the present disclosure encompasses forms obtained by various modifications, to the embodiments, that can be conceived by those skilled in the art and forms obtained by combining elements in different embodiments without departing from the spirit of the present disclosure.

For example, as in AI chip 5 illustrated in FIG. 12, one memory die may not be stacked directly on the first layout pattern of another memory die. That is, a memory die in the upper layer may be stacked above the layout pattern of a memory die in the lower layer, and a computing die may lie therebetween. Similarly, one computing die may not be stacked directly on the second layout pattern of another computing die. That is, a computing die in the upper layer may be stacked above the layout pattern of a computing die in the lower layer, and a memory die may lie therebetween. It should be noted that the memory dies, the computing dies, or the memory dies and the computing dies are stacked without having the interposer therebetween.

Moreover, computing dies 300 and 301 may be non-programmable circuits. Each of computing dies 300 and 301 may be provided with at least one AI process block 310 and may not be provided with logic blocks 320, switch blocks 330, and connection blocks 350.

Moreover, various modifications, substitutions, additions, omissions, and the like can be made to the embodiments above within the scope of the claims or equivalents thereof.

### INDUSTRIAL APPLICABILITY

The present disclosure can be used as AI chips of which processing power can be easily increased, and can be used for, for example, various electrical appliances, computing devices, and the like.

1. An artificial intelligence (AI) chip comprising:
a plurality of memory dies each for storing data;
a plurality of computing dies each of which performs a computation included in an AI process; and
a system chip that controls the plurality of memory dies and the plurality of computing dies, wherein
each of the plurality of memory dies has a first layout pattern,
each of the plurality of computing dies has a second layout pattern,
a second memory die which is one of the plurality of memory dies is stacked above the first layout pattern of a first memory die which is one of the plurality of memory dies, and
a second computing die which is one of the plurality of computing dies is stacked above the second layout pattern of a first computing die which is one of the plurality of computing dies.

2. The AI chip according to claim 1, wherein
the system chip includes the first memory die and the first computing die.

3. The AI chip according to claim 1, wherein
the system chip includes an interposer, and
at least one of the first memory die or the first computing die is stacked on the interposer.

4. The AI chip according to claim 3, wherein
the first memory die and the first computing die are stacked on the interposer.

5. The AI chip according to claim 1, wherein
the system chip includes a first region and a second region that do not overlap with each other in plan view,
the plurality of memory dies are stacked in the first region, and
the plurality of computing dies are stacked in the second region.

6. The AI chip according to claim 1, wherein
one of the first memory die and the first computing die is stacked above an other of the first memory die and the first computing die.

7. The AI chip according to claim 1, wherein
each of the plurality of computing dies includes a programmable circuit, and
the programmable circuit includes an accelerator circuit for the AI process.

8. The AI chip according to claim 7, wherein
the programmable circuit includes a logic block and a switch block.

9. The AI chip according to claim 1, wherein
the computation included in the AI process includes at least one of convolution operation, matrix operation, or pooling operation.

10. The AI chip according to claim 9, wherein
the convolution operation includes a computation performed in a logarithmic domain.

11. The AI chip according to claim 1, wherein
the AI process includes error diffusion dithering.

12. The AI chip according to claim 1, wherein
the system chip includes:
a control block; and
a bus that electrically connects the control block to the plurality of memory dies and the plurality of computing dies.

13. The AI chip according to claim 1, wherein
the plurality of first layout patterns are interconnected by through conductors.

14. The AI chip according to claim 1, wherein
the plurality of first layout patterns are interconnected wirelessly.

15. The AI chip according to claim 1, wherein
the plurality of second layout patterns are interconnected by through conductors.

16. The AI chip according to claim 1, wherein
the plurality of second layout patterns are interconnected wirelessly.
